(19) United States
(12) Patent Application Publication
(10) Pub. No.: US 2016/0136992 A1
(43) Pub. Date: May 19, 2016

(54) EMBEDDED NANOPARTICLE ANTI-COUNTERFEIT PATTERNING ON A SUBSTRATE AND METHOD OF MAKING THE SAME

(71) Applicant: EBO USA INC., Cambridge, MA (US)

(72) Inventors: CHAO-LUN MAI, Cambridge, MA (US); CHU-YUN HUANG, Cambridge, MA (US)

(21) Appl. No.: 14/944,215

(22) Filed: Nov. 18, 2015

Related U.S. Application Data
(60) Provisional application No. 62/081,451, filed on Nov. 18, 2014.

(51) Int. Cl. B42D 25/36; G03F 7/16

(52) U.S. Cl. CPC B42D 25/36; G03F 7/16

(57) ABSTRACT

A method of coating a substrate with an anti-counterfeit pattern is provided. The method includes at least following steps: providing a substrate; depositing a first particles on the substrate to form a first predetermined pattern; and depositing a second particles that are nanoparticles on the substrate to form a second predetermined pattern. The second particles are different from the first particles and repulsively interact with the first particles.

### FIELD

The subject matter herein relates to nanoparticle coated substrates and a method of continuously coating a substrate surface with nanoparticles.

### BACKGROUND

Thin film technology, wherein organic or inorganic particles with sizes on the order of 1-1000 nm are arranged in layers to form a film, is currently being used for an increasingly large number of different technological applications, including: information storage and transmission systems, chemical and biological sensors, optical and photonic devices, catalytic supports, energy harvesting and storage devices, thermal management devices, and other various products having surface property modification functionalities.

### BRIEF DESCRIPTION OF THE DRAWINGS

Implementations of the present technology will now be described, by way of example only, with reference to the attached figures.

FIG. 1 is a side plan view of an exemplary nanoparticle deposition apparatus.

FIG. 2 is a side plan view of another exemplary nanoparticle deposition apparatus.

FIG. 3 is a diagrammatic view illustrating the application of nanoparticles onto a surface of a substrate using the apparatus of FIG. 1.

FIG. 4 is a diagrammatic view illustrating the application of nanoparticles onto a surface of a substrate using the apparatus of FIG. 1, wherein the deposition plate is suspended above the substrate.

FIG. 5 is a free body diagram illustrating forces present during application of nanoparticles onto a substrate.

FIG. 6 is another free body diagram illustrating forces present during application of nanoparticles onto a substrate.

FIG. 7 is an exemplary embodiment of a deposition plate defining a plurality of channels therein.

FIG. 8 is another exemplary embodiment of a deposition plate defining a plurality of the plurality of channels therein.

FIG. 9 is an exemplary embodiment of a curved deposition plate.

FIG. 10 is another exemplary embodiment of a curved deposition plate.

FIG. 11 illustrates an exemplary method for forming an anti-counterfeiting mark on a substrate.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the examples described herein. However, it will be understood by those of ordinary skill in the art that the examples described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the examples described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “outside” refers to a region that is beyond the outermost confines of a physical object. The term “inside” indicates that at least a portion of a region is partially contained within a boundary formed by the object. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” means “including, but not necessarily limited to”; it specifically indicates open-ended inclusion or membership in a so-described combination, group, series and the like.

The term “nanoparticles” as described herein, means any particle having a diameter ranging from 1-1000 nm.

The present disclosure is described in relation to an apparatus for applying nanoparticles to a surface of a substrate. The present disclosure is further described in relation methods of using the apparatus disclosed herein for making nanoparticle coated substrates. Nanoparticle coated substrates produced in relation to the disclosed apparatus and methods are also disclosed herein.

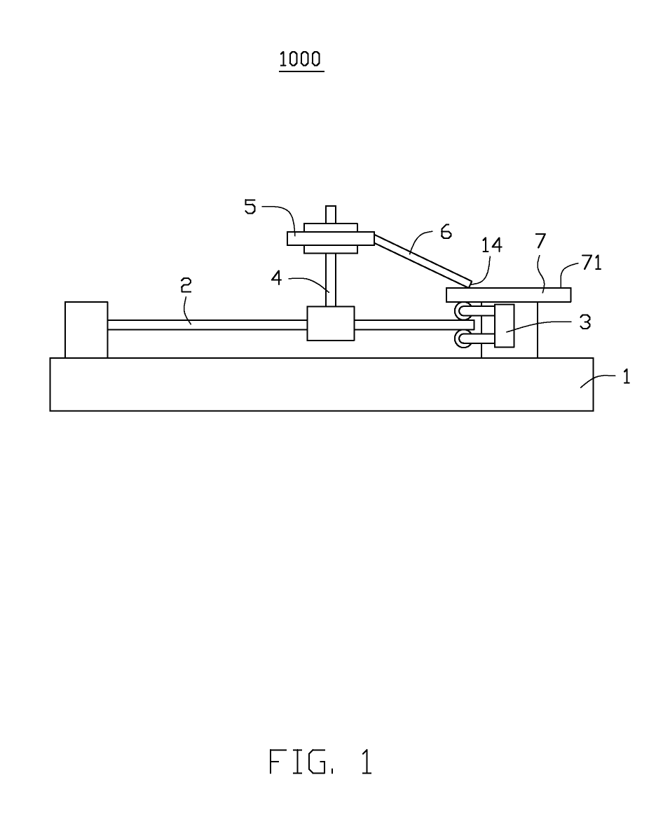

FIG. 1 illustrates an exemplary nanoparticle deposition apparatus 1000 for forming a nanoparticle thin film on a substrate. The deposition apparatus 1000 generally comprises a support member 4 coupled to a motor 3, a deposition plate 6 extending from the support member 4, a platform 7 having a flat surface 71 for receiving a substrate (not shown), the deposition plate 6 extending toward the flat surface 71 of the platform 7 at an acute angle. The motor 3 is configured to drive the support member 4 toward the deposition plate 6 such that an end 14 of the deposition plate 6 moves across the flat surface 71 of the platform 7, whereby nanoparticles are distributed along the surface of a substrate when received on the flat surface 71 of the platform 7. The general components described above are represented in FIG. 1 as follows. As shown in FIG. 1, the deposition apparatus 1000 can be mounted on a base 1 to secure the deposition apparatus 1000 for use. The deposition apparatus 1000 comprises a driving shaft 2 and a clamp 5. The support member 4 is moveably coupled to the drive shaft 2 and extending perpendicularly from the drive shaft 2. The clamp 5 is mounted on the support member 4. The motor 3 is attached to the base 1. The motor 3 can actuate the support member 4 to move along the length of the drive shaft 2. The motor 3 can be mechanical, electronic, electromagnetic, or any other suitable type of motor. The deposition plate 6 and the clamp 5 can be configured such that the deposition plate 6 couples to the clamp 5. The platform 7 can be coupled to a top surface of the motor 3 for receiving a substrate on which nanoparticles will be deposited.

In use, the deposition apparatus 1000 is designed such that a substrate is placed on the platform 7 and the deposition plate 6 extends toward the flat surface 71 of the platform 7 at an acute angle and contacts the substrate surface. Preferably, the deposition apparatus 1000 is configured such that the acute angle formed by the substrate and deposition plate 6 is greater than 25 degrees, more preferably greater than 45 degrees, and even more preferably the acute angle is 60 degrees. The acute angle can be changed by, for example, altering the overall height of the support member 4 relative to the platform 7. Alternatively, the acute angle can be changed by moving the clamp 5 to different locations of the support member 4. In other words, as the clamp 5 is moved higher vertically on the support member 4, the acute angle will be increased.

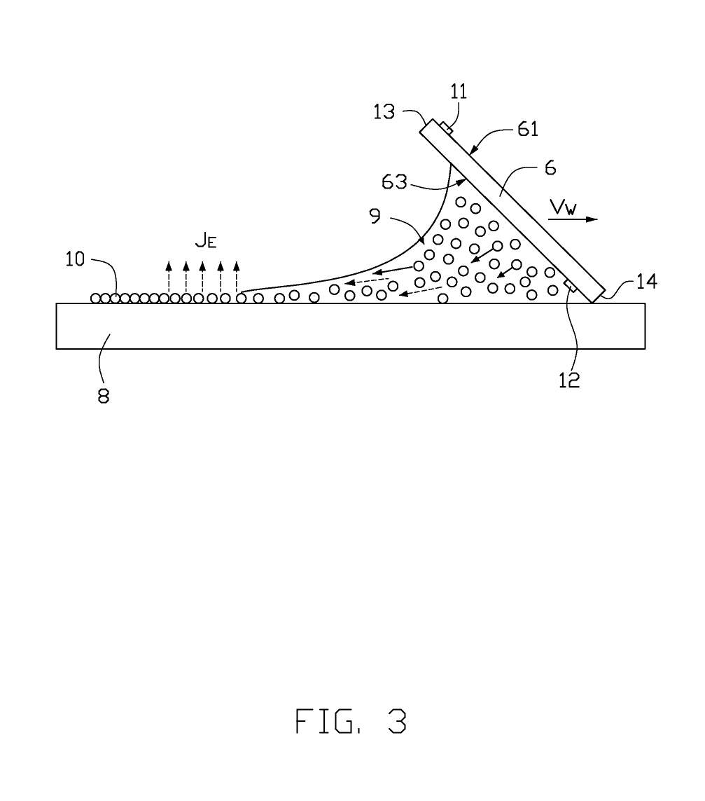

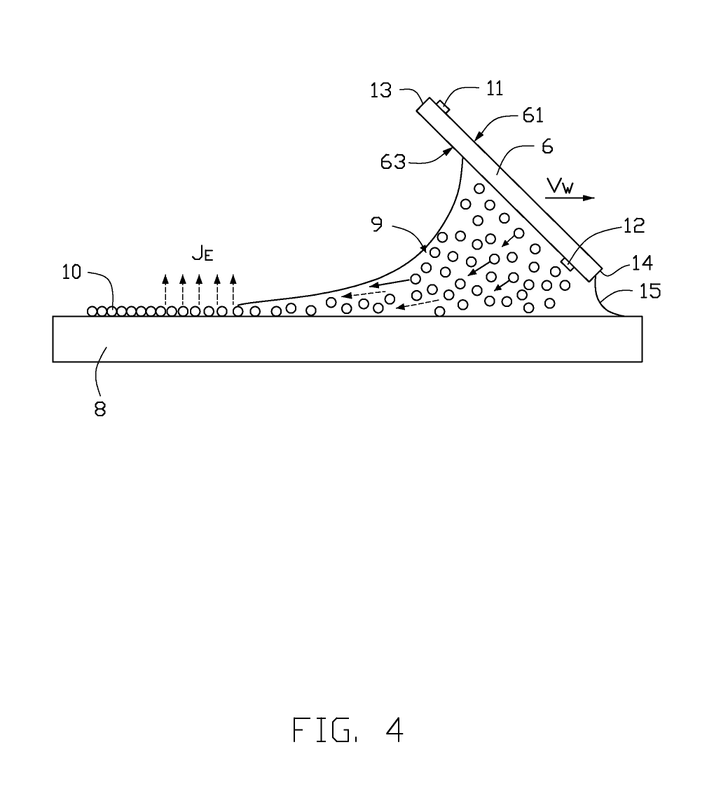

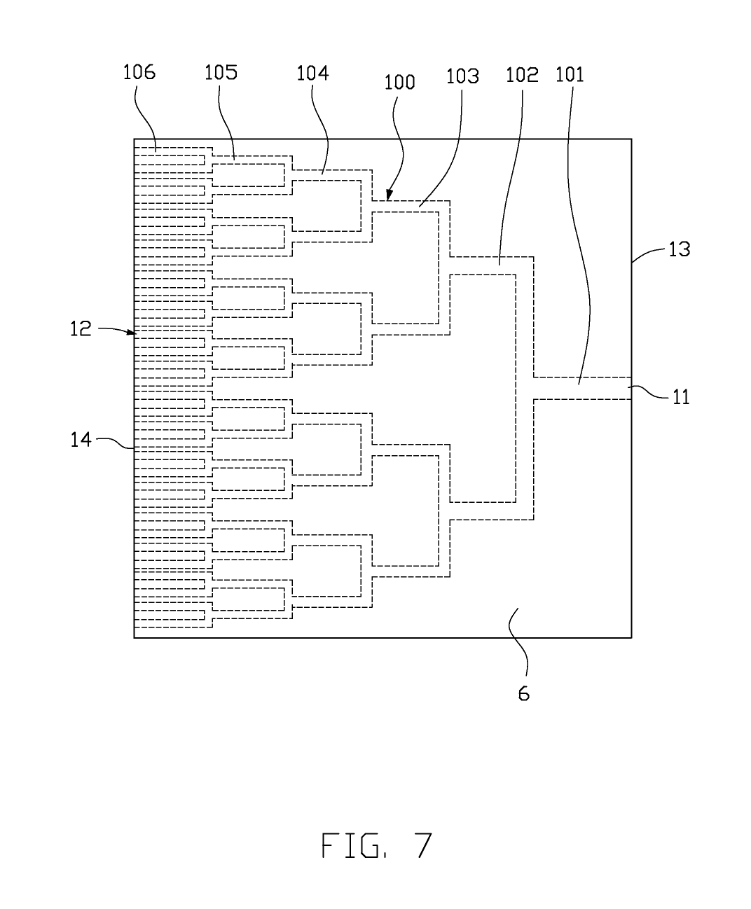

Furthermore, an inlet 11 can be provided on the top surface proximate the upper end 13 of the deposition plate 6 as shown in FIGS. 3 and 4. A plurality of outlet ports 12 (shown in detail in FIG. 7) can be provided on the undersurface of the deposition plate 6 near the lower end 14 of the deposition plate 6. A suspension can be provided in the inlet 11, and which passes through channels 100 (described in FIG. 7) in the deposition plate 6 and exits out from the outlet ports 12. The suspension can then coat a substrate provided beneath the deposition plate 6. The cross-sectional are of channels 101-106 follows Murray's law, such that the flow at the outlets ports 12 is substantially homogenous, and the flow direction is mainly parallel to the direction of nanoparticle accumulation on the substrate.

In one example, the deposition apparatus 1000 can be used to form a nanoparticle thin film wherein the thin film is a nanoparticle monolayer. In other examples, deposition apparatus can be used to form a nanoparticle thin film wherein the thin film has more than one nanoparticle layer.

In one exemplary embodiment, the deposition plate 6 physically contacts the substrate when in use. In alternative embodiments, the deposition plate 6 can be suspended above the substrate at while still forming the acute angle. In at least one embodiment, the deposition plate 6 is suspended up to 0.5 mm above the substrate surface. In other embodiments, the deposition plate 6 is suspended from about 40 m to about 0.5 mm above the substrate surface. The deposition plate 6 can be made of a metal, a metal alloy, a silicon oxide, a plastic, or any combination thereof.

The deposition plate 6 can also be made of a plastic, rubber, polymer or other deformable material such as, for example polydimethylsilicon (PDMS). The deformable deposition plate can be fabricated by any method commonly used by one of ordinary skill in art such as, for example, injection molding or other lithographic methods to solidify and crosslink certain parts of the deformable material while allowing the materials in the defined channel region to be removed. After injection molding or a lithographic process, the deformable deposition plate can be cured for a predetermined period of time. The amount of curing time can be varied to finely tune the degree of softness or hardness of the deposition plate. The deformable deposition plate can be formed into a shape corresponding to the shape of any substrate surface for deposition of nanoparticles. The deformable deposition plate can be formed to have, for example, a convex surface, and concave surface, and rippled or ridged surface, an oscillating series of local minima and maxima, or any other suitable shape.

In at least one embodiment, the deposition plate 6 and clamp 5 can be coupled such that an angle formed between the deposition plate 6 and clamp 5 is constant. In other embodiments, the deposition plate 6 and clamp 5 can be pivotably coupled such that an angle formed between the deposition plate 6 and clamp 5 can be changed during prior to or during use. The pivotable coupling can be independently changed by the user or can be changed in response to modification of the support member 4 and the clamp 5 as described above.

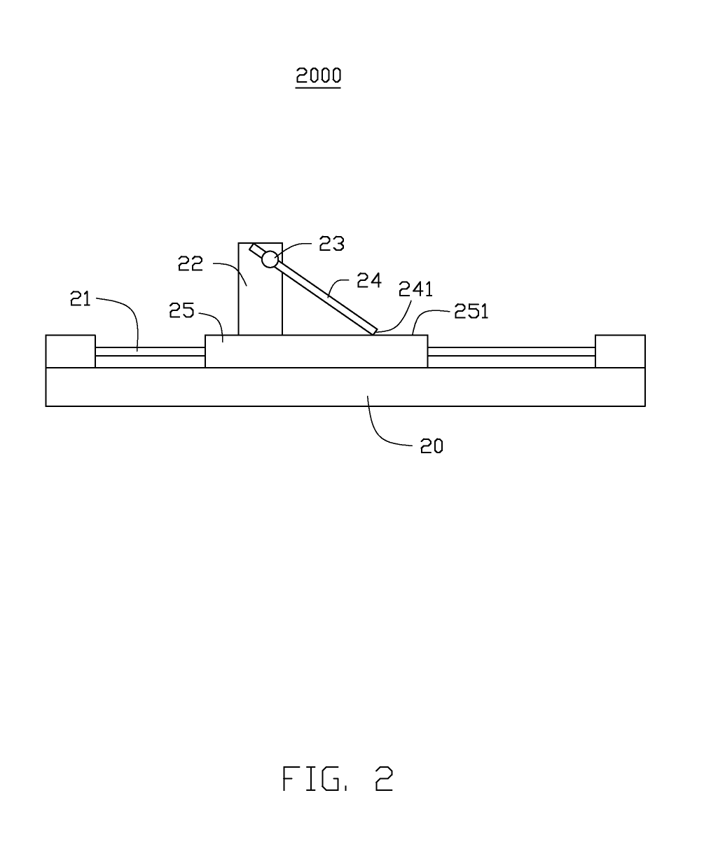

FIG. 2 illustrates another exemplary nanoparticle deposition apparatus 2000 for forming a nanoparticle thin film on a substrate (not shown). The deposition apparatus 2000 generally comprises a platform 25 coupled to a motive force (not shown, for example, a motor) via a drive shaft 21 and having a flat surface 251 for receiving a substrate, a deposition plate 24 extending from a support member 22, the deposition plate 24 extending toward the flat surface 251 of the platform 25 at an acute angle. The motive force is configured to drive the platform 25 toward the deposition plate 24 such that an end 241 of the deposition plate 24 moves across the flat surface 251 of the platform 25, whereby nanoparticles are distributed along the surface of a substrate when received on the flat surface 251 of the platform 25. The general components described above are represented in FIG. 2 as follows. As shown in FIG. 2, the deposition apparatus 2000 can be mounted on a base 20 to secure the deposition apparatus 2000 for use. The platform 25 is movably mounted on the drive shaft 21. The platform 25 is coupled to a motive force (not shown) which can actuate the platform 25 to move along the length of the drive shaft 21. The motive force can be mechanical, electronic, electromagnetic, or any other suitable type of motor. The deposition apparatus 2000 further comprises a clamping member 23 mounted on the support member 22. The deposition plate 24 and the clamping member 23 can be configured such that the deposition plate 24 couples to the clamping member 23. The support member 22, which is coupled to the base 20, secures the deposition plate 24 via the clamping member 23.

In use, the deposition apparatus 2000 is designed such that a substrate is placed on the platform 25 and the deposition plate 24 extends toward the flat surface 251 of the platform 25 at an acute angle and contacts the substrate surface. Preferably, the deposition apparatus 200 is configured such that the acute angle formed by the substrate and deposition plate 24 is greater than 25 degrees, more preferably greater than 45 degrees, and even more preferably the acute angle is 60 degrees. The acute angle can be changed by, for example, altering the overall height of the support member 22 relative to the platform 25. Alternatively, the acute angle can be changed by moving the clamping member 23 to different locations of the support member 22. In other words, as the clamping member 23 is moved higher vertically on support member 22, the acute angle will be increased.

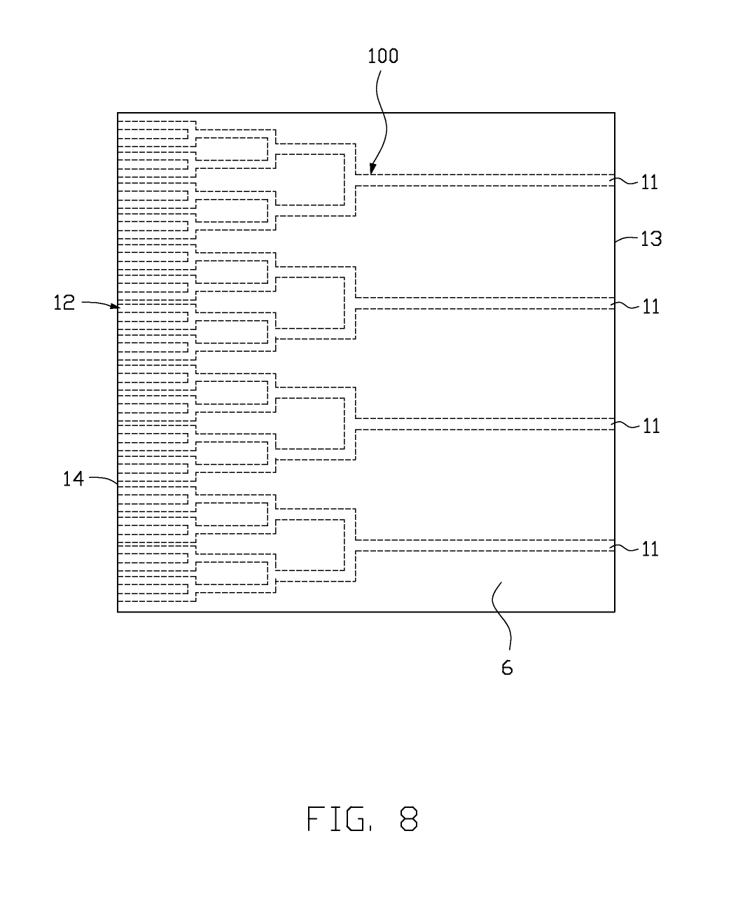

Furthermore, the deposition plate 24 shown in FIG. 2 is substantially similar to deposition plate 6 as shown in FIGS. 7-8. The deposition plate 24 may also define a plurality of channels having at least one inlet and a plurality of outlet ports.

In one embodiment, the deposition apparatus 2000 can be used to form a nanoparticle thin film wherein the thin film is a nanoparticle monolayer. In other embodiments, deposition apparatus can be used to form a nanoparticle thin film wherein the thin film has more than one nanoparticle layer.

The deposition plate 24 can be made of a metal, a metal alloy, a silicon oxide, a plastic, or any combination thereof. The deposition plate 24 can also be made of a plastic, rubber, polymer or other deformable material such as, for example polydimethylsilicon (PDMS). The deformable deposition plate can be fabricated by any method commonly used by one of ordinary skill in art such as, for example, injection molding or other lithographic methods to solidify and crosslink certain parts of the deformable material while allowing the materials in the defined channel region to be removed. After injection molding or a lithographic process, the deformable deposition plate can be cured for a predetermined period of time. The amount of curing time can be varied to finely tune the degree of softness or hardness of the deposition plate. The deformable deposition plate can be formed into a shape corresponding to the shape of any substrate surface for deposition of nanoparticles. The deformable deposition plate can be formed to have, for example, a convex surface, and concave surface, and rippled or ridged surface, an oscillating series of local minima and maxima, or any other suitable shape.

In at least one embodiment, the deposition plate 24 and the clamping member 23 can be coupled such that an angle formed between the deposition plate 24 and the clamping member 23 is constant. In other embodiments, the deposition plate 24 and the clamping member 23 can be pivotably coupled to the support member 22 such that an angle formed between the deposition plate 24 and the clamping member 23 can be changed prior to or during use. The pivotable coupling can be independently changed by the user or can be changed in response to modification of the support member 24 and clamping member 23 as described above.

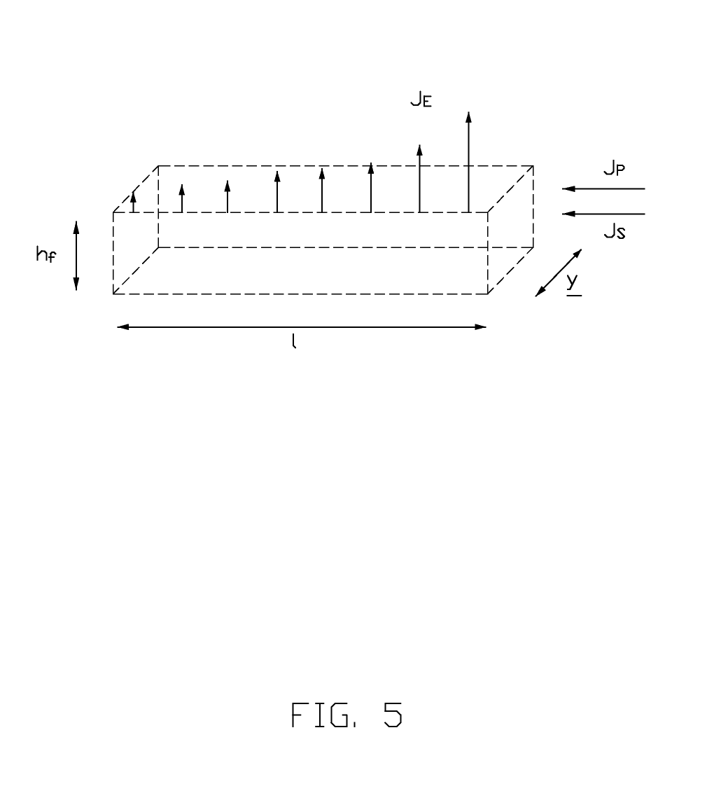

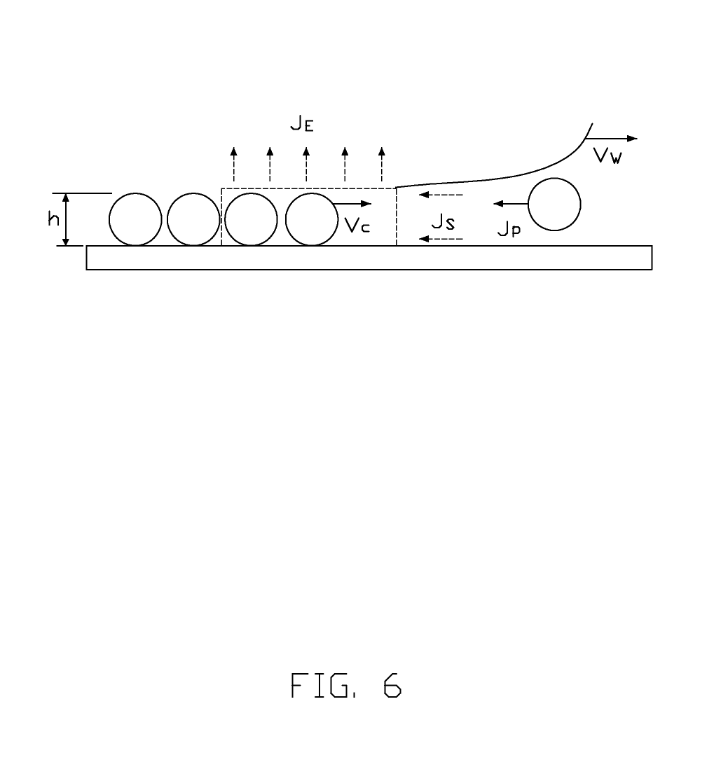

FIG. 3 is a diagrammatic view illustrating the application of nanoparticles onto a surface of a substrate 8. In use, the deposition plate 6 is placed in contact with the substrate 8 at an acute angle. A predetermined amount of a suspension 9 comprising a solvent and nanoparticles is placed in the acute angle formed between the deposition plate 6 and the substrate 8. The suspension 9 is attracted to the surfaces of the deposition plate 6 and the substrate 8 by capillary force. The deposition plate 6 is then moved along the surface of the substrate 8 from the left hand portion of the substrate toward the right hand portion of the substrate at a predefined coating speed V_{w}. As the deposition plate 6 is moved along the substrate 8, the solvent will evaporate as defined by J_{E}, the flux of the evaporating solvent, leaving a nanoparticle thin film 10. The forces and interactions leading to formation of the thin film 10 are described below in view of FIGS. 5 and 6.

As discussed above, in one exemplary embodiment, the deposition plate 6 physically contacts the substrate 8 when in use as shown in FIG. 3. In alternative embodiments, the deposition plate 6 can be suspended above the substrate 8 at while still forming the acute angle as shown in FIG. 4. In at least one embodiment, the deposition plate 6 is suspended up to 0.5 mm above the substrate surface as shown. In other embodiments, the deposition plate 6 is suspended from about 40 μm to about 0.5 mm above the substrate surface. The deposition plate 6 can be made of a metal, a metal alloy, a silicon oxide, a polymer, a plastic, or any combination thereof.

Also, as shown in FIG. 4, when the deposition plate 6 is suspended above the substrate 8, two opposite meniscuses 15 are formed between the substrate 8 and the deposition plate 6.

The nanoparticles used can be any type of nanoparticles and this disclosure is not intended to be limited for any specific type of application. In some embodiments, the nanoparticles can comprise silicon or silicon oxides. In other embodiments, the nanoparticles can comprise one or more organic polymers or organic dendrites such as polymethyl methacrylate (PMMA), polycarbonate (PC), polystyrene (PS), polyether ether ketone (PEEK), polyetherimide (PEI), or any other similar organic species. In other embodiments, the nanoparticles can be metals or inorganic oxides such as, for example, aluminum, gold, silver, copper, silicon oxide, aluminum oxide, titanium oxide, indium tin oxide, iron oxide, zinc oxide, or any other desired metal or metal oxide composition. In yet other embodiments, the nanoparticles can be core-shell nanocomposites such as zinc sulfide or cadmium sulfide quantum dots, metal nanoparticles or metal oxide nanoparticles coated with an organic polymer or other functionality, or any other similar core-shell type nanoparticle. In yet other embodiments, the nanoparticles can comprise biological species such as proteins, enzymes, immunoglobulins, or any other suitable biological species. In yet further embodiments, the nanoparticles can comprise more than one of any of the nanoparticle type discussed above. The nanoparticles can exhibit properties specific for any use. For example, the nanoparticles can be magnetic, opto-electronic, chemiluminescent, phospholuminescent, any other desired property in application.

The solvent or solvent mixture used can be any type of solvent or solvent mixture and this disclosure is not intended to be limited for any specific type of application. In general, the solvent or solvent mixture should promote uniform dispersion of the nanoparticles in the suspension, be capable of evaporation under ambient or slightly elevated temperature conditions, and facilitate formation of a uniform nanoparticle monolayer. Preferably, deionized (DI) water is used. In alternative embodiments, a polar organic solvent, such as alcohols (for example, methanol, ethanol and isopropanol), dialkyl ethers (for example diethyl ether or diphenyl ether), ketones (for example, acetone) or any similar solvents can be used. In yet further alternative embodiments, mixtures of DI water, methanol, ethanol, diethyl ether, acetone or any similar solvents can be used.

FIG. 5 is a free body diagram illustrating forces present during application of nanoparticles onto a substrate. FIG. 6 is another free body diagram illustrating forces present during application of nanoparticles onto a substrate. The formation of a nanoparticle thin film layer onto a substrate surface can be understood by one of ordinary skill in the art in view of the following equations in relation to FIGS. 5 and 6. The following equations are made with the consideration that a control volume that encompasses a drying region of a thin evaporating film and the control moves as the film dries. The following equations further are modeled under the premise that the y-direction axis does not change and therefore the model can be simplified to a y-independent case. This assumption is especially true for large-area fabrication, where the width of the deposition plate (in y-direction) is large.

In the following equations J_{E} is the flux of the evaporating solvent, J_{P} is the flux of the nanoparticles, J_{S} is the flux of the solvent, y is the unit length of the substrate in the y-direction, Nₛ is the total number density of the solvent molecules, Vₛ is the volume per solvent molecule, vₛ is the flow velocity of the solvent entering the drying region, Nₚ is the total number density of the nanoparticles, Vₚ is the volume per nanoparticle, vₚ is the flow velocity of the nanoparticles entering the drying region, vₑ is the rate of nanoparticle accumulation, ε is the void fraction in the accumulated particle film, h_{f} is the thickness of the control volume, h is the final particle film thickness, φₚ is the volume fraction of nanoparticles in the original suspension undergoing deposition, and β is correlation value.

Under steady state conditions, by conservation of volume:

J_{S}=J_{E} (1)

When the flux of the solvent and the flux of the evaporating solvent are expressed as local average fluxes the following equation can be derived:

J_{g}=y·∫0^{h}^{_{f}}jₛ′(z)dz=y·∫0^{h}^{_{f}}Nₛ′(z)VₛVₓ′(z)dz=jₛh_{f}y

J_{g}=y·∫0^{∞}jₑ′(x)dx=jₑly (2)

where

jₛ=NₛVₛvₛ (3)

and

jₚ=NₚVₚvₚ (4)

Under the steady state approximation, the combination of equations 1 and 3 yields:

$${J}_{E} = {j}_{e} l \underline{y} = {j}_{s} {h}_{f} \underline{y} = {J}_{S} , and {j}_{s} = {N}_{s} {V}_{s} {v}_{s} \\ ⇒ \frac{{j}_{e} l}{{h}_{f}} = {N}_{s} {V}_{s} {v}_{s} \\ ⇒ {v}_{s} = \frac{{j}_{e} l}{{N}_{s} {V}_{s} {h}_{f}} \qquad ( 5 )$$

Because there is no exiting flux of, but rather an accumulation of nanoparticle growing at a rate of vₑ, equation 4 can be expressed as follows:

Jₚ=jₚh_{f}y=NₚVₚvₚhⱼy, and Jₚ=v_{c}(1−ε)hy (6)

Because the nanoparticles are dispersed in solvent, the nanoparticles will move with the solvent flow. Therefore, the particle flow rate can be considered proportional to the solvent flow rate as follows:

vₚ=βvₚₛ (7)

and

NₚVₚvₚhⱼyNₚVₚβvₛhⱼy=vₑ(1−ε)hy (8)

The combination of equations 5 and 8 yields:

$${N}_{p} {V}_{p} β {v}_{s} {h}_{f} = {N}_{p} {V}_{p} β \frac{{j}_{e} l}{{N}_{s} {V}_{s} {h}_{f}} {h}_{f} = {v}_{c} ( 1 - ɛ ) h \\ ⇒ β {j}_{e} l \frac{{N}_{p} {V}_{p}}{{N}_{s} {V}_{s}} = {v}_{c} ( 1 - ɛ ) h \qquad ( 9 )$$

The ratio of NₚVₚ/NₛVₛ in equation 9 can be rewritten as φ_{P}/(1−φₚ), where φₚ is the volume fraction of particles in the original suspension being deposited, and φₛ=1⊕φₚ is the corresponding solvent volume fraction, yielding:

$$β {j}_{e} l \frac{{φ}_{p}}{1 - {φ}_{p}} = {v}_{c} ( 1 - ɛ ) h , ⇒ {v}_{c} = \frac{β {j}_{e} l {φ}_{p}}{h ( 1 - {φ}_{p} ) ( 1 - ɛ )} \qquad ( 10 )$$

The correlation value β is dependent upon particle-particle, particle-solvent, or particle-substrate interactions. Since the solvent molecule is assumed to flow more freely than the particle, the value of β is assumed to be in the range of 0-1. Stronger interaction between particles or between the particle and the substrate results in smaller value of β. Also, for non-adsorbing particles and dilute suspensions, β≈1.

Due to the difficulty of determining the jₑ of thin film materials experimentally, βjₑI can be converted to a single variable K, yielding:

$${v}_{c} = \frac{K {φ}_{p}}{h ( 1 - {φ}_{p} ) ( 1 - ɛ )} \qquad ( 11 )$$

For a monolayer of monodisperse spherical nanoparticles oriented in a closed packed hexagonal structure, 1−ε=0.605, and h equals the diameter of the spherical nanoparticles. The single variable K can then be calculated upon determination of vₑ.

A method of making a nanoparticle coated substrate using the deposition apparatus 1000 described above is also provided herein by way of example, as there are a variety of ways to carry out the method. The method described below can be carried out using the configurations illustrated in FIGS. 1 and 3-6, for example, and various elements of these figures are referenced in explaining an example method. The procedure described below is illustrative only and the order of the blocks can change according to the present disclosure. Additional steps may be added or fewer steps may be utilized, without departing from this disclosure.

First a substrate is secured to the platform. After securing the substrate, the deposition plate is placed above the substrate such that an acute angle is formed between the deposition plate and the substrate. Preferably, the acute angle formed by the substrate and deposition plate is greater than 25 degrees, more preferably greater than 45 degrees, and even more preferably the acute angle is 60 degrees. The acute angle is formed at an end of the substrate that is closest to the support member. In at least one embodiment, the deposition plate can be positioned such that it contacts the substrate. In other embodiments, the deposition plate can be suspended above the substrate at while still forming the acute angle. In at least one embodiment, the deposition plate is suspended up to 0.5 mm above the substrate surface. In other embodiments, the deposition plate is suspended from about 40 μm to about 0.5 mm above the substrate surface.

A suspension comprising a solvent and nanoparticles is then applied to an area between the deposition plate and the substrate by continuous flow of the suspension such that the suspension contacts the deposition plate and substrate and forms a meniscus between the deposition plate and the substrate. The suspension is delivered via the inlet ports and outlet ports to the area between the deposition plate and the substrate. The continuous flow can be controlled by the user or by the continuous depletion of the meniscus during deposition. The suspension can have 1-50 volume % of nanoparticles, more preferably 20-50 volume %, and even more preferably about 40 volume %.

After applying the suspension between the deposition plate and substrate, the motor is actuated to drive the support member and deposition plate to move toward the end of the substrate away from the support member to spread the suspension along the surface of the substrate. The motor can drive the support member to move for a predetermined distance or the length of the substrate over a predetermined rate of speed. The deposition speed can range from 1 μm/s to 200 μm/s, preferably 20-100 μm/s, and even more preferably 60 μm/s. After spreading the suspension on the substrate, the suspension solvent is removed and the formed nanoparticle coated substrate is allowed to dry. Once removal of the solvent has been accomplished, the nanoparticle coated substrate can be removed from the platform.

The method is preferably carried out under ambient conditions ranging from 16-22° C., and more preferably 18° C., and in an environment having a relative humidity ranging from 35-55%.

A method of making a nanoparticle coated substrate using the deposition apparatus 2000 described above is also provided herein by way of example, as there are a variety of ways to carry out the method. The method described below can be carried out using the configurations illustrated in FIGS. 2-6 for example, and various elements of these figures are referenced in explaining an example method. The procedure described below is illustrative only and the order of the blocks can change according to the present disclosure. Additional steps may be added or fewer steps may be utilized, without departing from this disclosure.

First a substrate is secured to the platform. After securing the substrate, the deposition plate is placed above the substrate such that an acute angle is formed between the deposition plate and the substrate. Preferably, the acute angle formed by the substrate and deposition plate is greater than 25 degrees, more preferably greater than 45 degrees, and even more preferably the acute angle is 60 degrees. The acute angle is formed at an end of the substrate that is closest to the support member. In at least one embodiment, the deposition plate can be positioned such that it contacts the substrate. In other embodiments, the deposition plate can be suspended above the substrate at while still forming the acute angle. In at least one embodiment, the deposition plate is suspended up to 0.5 mm above the substrate surface. In other embodiments, the deposition plate is suspended from about 40 μm to about 0.5 mm above the substrate surface.

A suspension comprising a solvent and nanoparticles is then applied to an area between the deposition plate and the substrate by continuous flow of a nanoparticle containing suspension such that the suspension contacts the deposition plate and substrate and forms a meniscus between the deposition plate and the substrate. The nanoparticle suspension is delivered via the inlet ports and outlet ports to the area between the deposition plate and the substrate. The continuous flow can be controlled by the user or by the continuous depletion of the meniscus during deposition. The suspension can have 1-50 volume % of nanoparticles, more preferably 20-50 volume %, and even more preferably about 40 volume %.

After applying the suspension between the deposition plate and substrate, the motor is actuated to drive the platform to move in a direction opposite the acute angle formed between the deposition plate and the substrate to spread the suspension along the surface of the substrate. The motor can drive the platform to move for a predetermined distance or the length of the substrate over a predetermined rate of speed. The deposition speed can range from 1 μm/s to 200 μm/s, preferably 20-100 μm/s, and even more preferably 60 μm/s. After spreading the suspension on the substrate, the suspension solvent is removed and the formed nanoparticle coated substrate is allowed to dry. Once removal of the solvent has been accomplished, the nanoparticle coated substrate can be removed from the platform.

The method is preferably carried out under ambient conditions ranging from 16-22° C., and more preferably 18° C., and in an environment having a relative humidity ranging from 35-55%.

As shown in FIG. 7, the deposition plate 6 can have a plurality of channels 100 which extend in stages from an inlet 11 to a plurality of outlet ports 12. The suspension 9 can be provided at the inlet 11, which passes through the plurality of channels 11 and then exits the plurality of outlet ports 12. The channels 100 are provide through the deposition plate 6 in a tree pattern and which increase in number extending from the inlet 11 to the outlet ports 12. In particular, stages 101 through 106 each doubles in the number of channels 100 with each successive stage. For example, in the first stage 101, there is one channel. This stage 101 doubles to two channels 100 in stage 102. Each of the channels 100 in stage 102 doubles such that there are four channels 100 in stage 103. Successively, in the next stage 104 each of the channels in the previous stage doubles to eight channels in 104, sixteen channels 100 in stage 105, and thirty two channels 100 at stage 106. After stage 106, any provided suspension would then exit the plurality (thirty two in this case) of outlet ports 12.

By use of the channels 100, a wider area of a substrate can be coated by the deposition plate 6. Referring back to FIGS. 3 and 4, the inlet 11 can be placed at the top deposition plate 6 for receiving suspension 9. The suspension 9 is input into the inlet 11, and passes through the channels 100, and out the plurality of outlet ports 12. With each stage, the width of the plurality of outlet ports 12 from end to end increase, such that a wider area of a substrate can be coated. In some examples, the number of channels 100 increases exponentially at each stage. To avoid sedimentation of the nanoparticles in the channel, the coating plat can be aid with ultrasonic vibrator or other RF/optical methods, where the particles absorbs the wave energy and become more thermally active to avoid sedimentation. The inner surface of the channels can also be coated with various functional chemical agent that repels a particular nanoparticle used.

The channels can have any cross-section shape, for example, circular, square, rectangular or other polygonal shape. Also, as shown in FIG. 5, the each of the individual channels 100 can decrease in size (i.e. diameter, radius, width), such that at each successive stage, the cross-sectional area of channels 100 are smaller. In particular, the size of the channels for each successive stage can follow Murray's law (for circular cross-section of the channel) or modified Murray's law (for square cross sections or other shape). For example, the cross-section area of each sub daughter branch also follows Murray's law. Proportioning the size of the channels according to Murray's law can aid in optimizing flow through the channel system. For example, the radii can follow the following formula:

rₚ³=r_{d1}³+r_{d2}³+r_{d3}³+ . . . +r_{dn}³

In this case, rₚ is the radius of the parent branch, i.e., the inlet channel.

As shown in FIG. 8, the top end 13 can have a plurality of inlets 11, each having a plurality of stages and channels 100, and ending at a plurality of outlet ports 12. By adding additional inlets at the top end 13, fewer stages can be employed while still achieving a broader area of coating. However, one may also combine all the inlets 11 to have a sole inlet. Furthermore, the lower end 14 can be angled to facilitate the coating process. Fluid (such as ink) enters the inlet 11, and exits the plurality of outlet ports 12 to coat the substrate 8 on the platform 20.

In some examples, the suspension provision and coating can be conducted at a constant (continuous) speed, such that there is a constant flow of the suspension 9 at the outlet. Accordingly, a continuous process can be provided, where the suspension can be provided continuously to the inlets 11, and at a rate equal to particle assembly (coating) on the substrate and evaporation rate of the solvent.

The deposition plate illustrated in FIGS. 7 and 8 can also be made of a plastic, rubber, polymer or other deformable material such as, for example polydimethylsilicon (PDMS). The deformable deposition plate can be fabricated by any method commonly used by one of ordinary skill in an such as, for example, injection molding or other lithographic methods to solidify and crosslink certain parts of the deformable material while allowing the materials in the defined channel region to be removed. After injection molding or a lithographic process, the deformable deposition plate can be cured for a predetermined period of time. The amount of curing time can be varied to finely tune the degree of softness or hardness of the deposition plate. The deformable deposition plate can be formed into a shape corresponding to the shape of any substrate surface for deposition of nanoparticles. The deformable deposition plate can be formed to have, for example, a convex surface, and concave surface, and rippled or ridged surface, an oscillating series of local minima and maxima, or any other suitable shape.

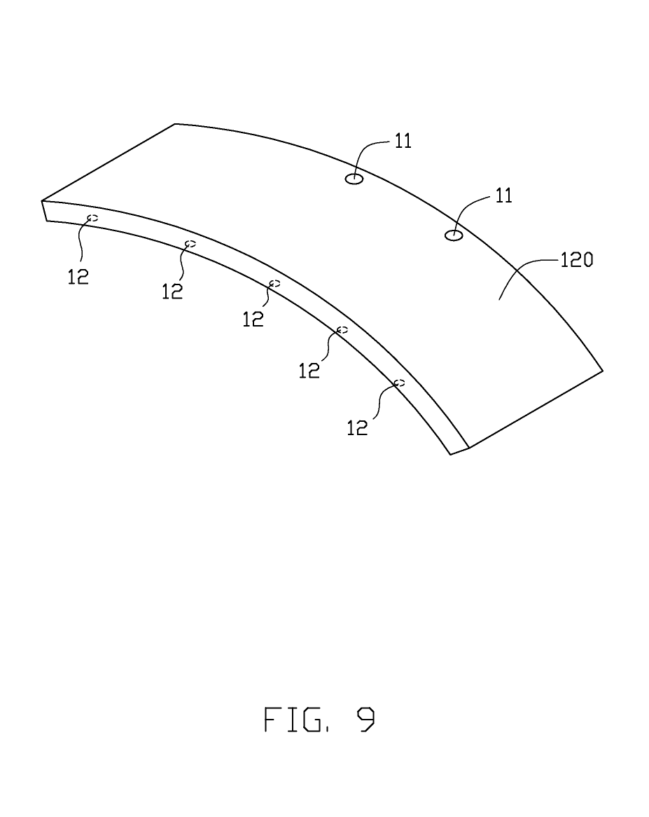

FIG. 9 is an exemplary illustration of a curved deposition plate 120. The curved deposition plate 120 can have a plurality of channels (not shown) formed as described with respect to FIGS. 7 and 8. The channels increase in number, doubles every stage from a plurality of inlets 11 to a plurality of outlet ports 12. In other examples, the channels do not double in number but are made up of a single channel from each of the plurality of inlets 11 to the plurality of outlet ports 12. The curved deposition plate 120 has a curved shape. The curved deposition plate 120 can also be described as having an arcuate shape. Such shape can aid in coating a curved substrate. In other examples, the deposition plate can have any other shape to conform to the shape of the substrate.

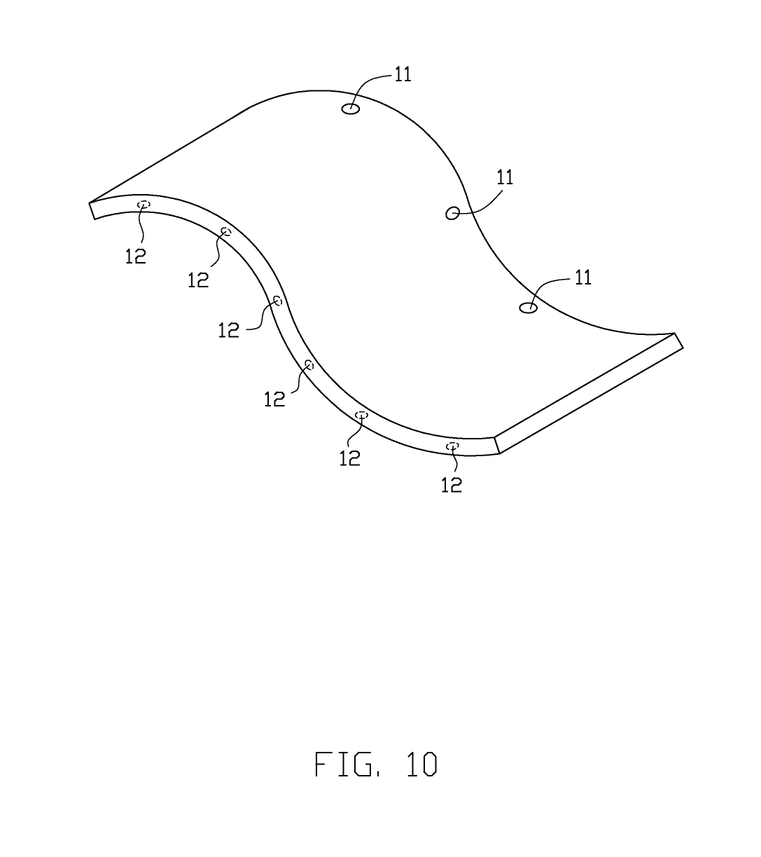

For example, as shown in FIG. 10 is an exemplary illustration of a curved deposition plate 121. The curved deposition plate 121 can have a first curve followed by an inverted curve, or a wave pattern, having a trough and a crest. The wave pattern can have repeated troughs and crests. The curved deposition plate 121 can have a plurality of channels (not shown) formed as described with respect to FIGS. 7-9. For example, the channels can increase in number from a plurality of plurality of inlets 11 to a plurality of outlet ports 12. For example, the channels can have a plurality of stages where the channels double at each successive stage. In other examples, the channels do not double in number but are made up of a single channel from each of the plurality of inlets 11 to the plurality of outlet ports 12. Such shape can aid in coating a curved substrate.

While not to be held to any particular hypothesis, the following derivation is provide to achieve a steady state continuous process.

To continuously supply solution, consider the steady state of volume conservation

Jᵢₙ=J_{M}+J_{P}+J_{S} (12)

With equations (2) and (6), the equation (12) can be rewritten as (wherein the subscript ink is an exemplary incoming coating solution), and
Jᵢₙ: the flux of incoming ink supply
J_{M}: the flux of evaporating solvent from the meniscus
J_{E}: the flux of evaporating solvent from the drying film
J_{P}: the flux of particle
J_{S}: the flux of solvent

$$\begin{matrix}{J}_{ink} = {J}_{M} + {j}_{p} {h}_{f} \underline{y} + {j}_{s} {h}_{f} \underline{y} \\ = {J}_{M} + ( {N}_{p} {V}_{p} {v}_{p} ) {h}_{f} \underline{y} + ( {N}_{s} {V}_{s} {v}_{s} ) {h}_{f} \underline{y} \\ = {J}_{M} + ( {N}_{p} {V}_{p} {v}_{p} ) {h}_{f} \underline{y} + ( {N}_{s} {V}_{s} \frac{{v}_{p}}{β} ) {h}_{f} \underline{y} \frac{{N}_{p} {V}_{p}}{{N}_{p} {V}_{p}} \\ = {J}_{M} + ( {N}_{p} {V}_{p} {v}_{p} ) {h}_{f} \underline{y} + ( {N}_{p} {V}_{p} \frac{{v}_{p}}{β} ) {h}_{f} \underline{y} \frac{{N}_{s} {V}_{s}}{{N}_{p} {V}_{p}} \\ = {J}_{M} + ( {N}_{p} {V}_{p} {v}_{p} ) {h}_{f} \underline{y} + \frac{1}{β} ( {N}_{p} {V}_{p} {v}_{p} ) {h}_{f} \underline{y} \frac{{N}_{s} {V}_{s}}{{N}_{p} {V}_{p}} \\ = {J}_{M} + {v}_{c} ( 1 - ɛ ) h \underline{y} + \frac{1}{β} {v}_{c} ( 1 - ɛ ) h \underline{y} \frac{1 - {φ}_{p}}{{φ}_{p}} \\ = {J}_{M} + {v}_{c} ( 1 - ɛ ) h \underline{y} ( 1 + \frac{1}{β} \frac{1 - {φ}_{p}}{{φ}_{p}} )\end{matrix} \qquad ( 13 )$$

For a coating area with width w, the unit length y in (13) should be replaced by to have

$${J}_{ink} = {J}_{M} + {v}_{c} ( 1 - ɛ ) hw ( 1 + \frac{1}{β} \frac{1 - {φ}_{p}}{{φ}_{p}} ) \qquad ( 14 )$$

where
v_{c}: experimentally obtained
1−ε=0.605
h=0, the diameter of the colloidal partical
w: the desired coating width
β: value between 0-1, with most cases approaches 1
φₚ: the volume concentration of the colloidal ink

Note that one may have

$${J}_{ink , nA} = {J}_{M} + {v}_{c , nA} ( 1 - ɛ ) hw ( 1 + \frac{1}{β} \frac{1 - {φ}_{p}}{{φ}_{p}} ) , \\ n = 1 , 2 , 3 … \qquad ( 15 )$$

Where

TABLE 1
Relation between Number of Layers,
Microsphere Packing Type (hexagonal Δ or square □),
Film Thickness (h), and Packing Fraction (1 − ε)^{a}

| n | film thickness, h | (1 − ε) |
|---|---|---|
| 1Δ | D_{P} | 0.6046 |
| 2□ | 1.707 D_{P} | 0.6134 |
| 2Δ | 1.817 D_{P} | 0.6657 |
| 3□ | 2.414 D_{P} | 0.6506 |
| 3Δ | 2.633 D_{P} | 0.6889 |

One may design a deposition plate that can continuously supply the colloidal ink with designed coating knife geometric profile and designed ambient environment (e.g. RH and T), such that the evaporation flux at the meniscus is much smaller comparing to the particle flux and solvent flux (which is equal to the evaporation flux J_{S}=J_{E}), namely J_{M}=J_{P}+J_{S}.

Then, equation (15) can be simplified with better control, as

$${J}_{ink , nA} \approx {v}_{c , nA} ( 1 - ɛ ) hw ( 1 + \frac{1}{β} \frac{1 - {φ}_{p}}{{φ}_{p}} ) , \\ n = 1 , 2 , 3 … \qquad ( 16 )$$

The present disclosure also provides for creating an anti-counterfeit pattern embedded within a nanoparticle patterned surface. In particular, the anti-counterfeit pattern can be created in a similar manner as a first pattern. For example, the deposition plate as described above can be configured to move in a first pattern for coating a substrate with nanoparticles in a first pattern or distribution. The deposition plate can be further configured to move in a second pattern and the nanoparticles are distributed in a second pattern. The second pattern can be one that allows for establishing an anti-counterfeiting pattern. First, the anti-counterfeit region can be defined using hydrophobic, hydrophilic, oleophobic, or oleophilic functional groups (depending on the property of substrate, nanoparticle, and the solvent) through a nano-contact printing method. Second, the coating method is used to coat nanomaterials onto the substrate where a hydrophobic anti-counterfeit pattern is defined. Due to the hydrophobicity at the region of the anti-counterfeit pattern, de-wet effect will be created such that the nanoparticle containing solution cannot cover that region, and hence no self-assembled nanoparticles will cover the region.

The present disclosure includes an apparatus for creating anti-counterfeit applying nanoparticles to a surface of a substrate. The apparatus can include a support member. The apparatus can include a deposition plate extending from the support member, and a platform having a flat surface for receiving a substrate. The deposition plate can be configured to move toward the platform such that an end of the deposition plate moves across the substrate, whereby nanoparticles are distributed along the substrate. The distribution of the nanoparticles in the second predetermined pattern is different from the first predetermined pattern, and the second predetermined pattern is such that it can be detected for preventing counterfeiting.

The present disclosure also includes a method of coating a substrate with an anti-counterfeit pattern of nanoparticles. The method can further include moving the deposition plate relative to a substrate secured on a platform in a first predetermined pattern. Additionally, the method can further include depositing nanoparticles on a substrate as the deposition plate moves along the substrate surface in the first predetermined pattern; moving the deposition plate relative to the substrate in a second predetermined pattern. Furthermore, the method can further include depositing nanoparticles on the substrate as the deposition plate moves relative to the substrate in the second predetermined pattern, wherein the second predetermined patter is different from the first predetermined pattern and establishes an anti-counterfeiting structure on the substrate.

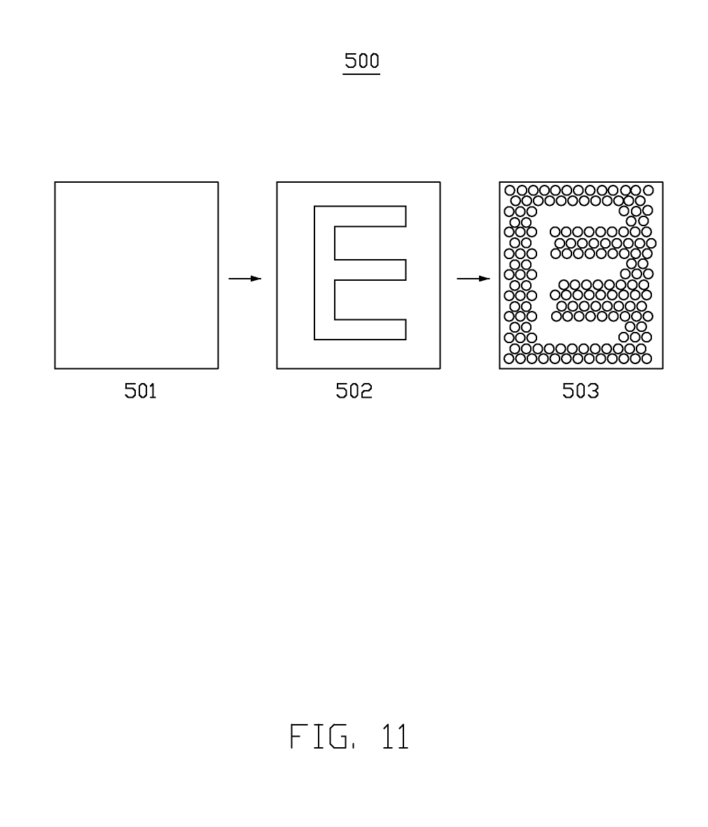

FIG. 11 is illustrates an exemplary method for forming an anti-counterfeiting mark on a substrate. The method 500 is provided by way of example, as there are a variety of ways to carry out the method. The method 500 described below can be carried out using the apparatus illustrated in FIG. 1, for example, and various elements of these figures are referenced in explaining example method 500. Each block shown in FIG. 11 represents one or more processes, methods or subroutines, carried out in the example method 500. Furthermore, the illustrated order of blocks is illustrative only and the order of the blocks can change according to the present disclosure. Additional blocks may be added or fewer blocks may be utilized, without departing from this disclosure. The example method 500 can begin at block 501.

In block 501, a substrate having a cleaned surface is provided. In this case the substrate is a hydrophilic glass substrate.

In block 502, a hydrophobic composition is immobilized on the surface of the substrate. The hydrophobic composition, as shown, is in the shape of the letter “E”. While the hydrophobic composition is immobilized in this example method in the form of a letter, other marks such as numbers, words, shapes, trademarks, logos, pictures, or any desired form can be immobilized on the hydrophilic substrate.

In block 503, a layer of hydrophilic nanoparticles is formed on the substrate using the method outlined above with regard to FIGS. 1-4. The formed substrate is then removed from the deposition apparatus for use.

While exemplary method 500 uses a hydrophilic substrate, a hydrophobic composition and hydrophilic nanoparticles, other exemplary methods may use a hydrophobic substrate, a hydrophilic composition, and hydrophobic nanoparticles. In general, the applied composition and the nanoparticles should repulsively interact with each other.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A method of coating a substrate with an anti-counterfeit pattern, comprising:
providing a substrate;
depositing first particles on the substrate to form a first predetermined pattern; and
depositing second particles that are nanoparticles on the substrate to form a second predetermined pattern;
wherein the second particles are different from the first particles and repulsively interact with the first particles.

2. The method of claim 1, wherein the first particles are nanoparticles, the step of depositing the first particles uses an apparatus, the apparatus comprises a support member, a deposition plate extending from the support member, and a platform for receiving a substrate, the support member and the platform are capable of moving relative to each other, enabling an end of the deposition plate to move across the surface of the platform, the step of depositing the first particles comprises:
securing the substrate on the platform;
forming an acute angle between the deposition plate and the substrate;
applying a first suspension comprising a solvent and the first particles to an area between the deposition plate and the substrate such that the first suspension forms at least one meniscus between the deposition plate and the substrate;
driving the deposition plate to move relative to the platform or driving the platform to move relative to the deposition plate, enabling the first suspension to spread on a surface of the substrate in the first predetermined pattern; and
removing the suspension solvent on the substrate.

3. The method of claim 1, wherein the step of depositing the second particles uses an apparatus, the apparatus comprises a support member, a deposition plate extending from the support member, and a platform for receiving a substrate, the support member and the platform are capable of moving relative to each other, enabling an end of the deposition plate to move across the surface of the platform, the step of depositing the second particles comprises:
securing the substrate having the first particles on the platform;
forming an acute angle between the deposition plate and the substrate;
applying a second suspension comprising a solvent and the second particles to an area between the deposition plate and the substrate such that the second suspension forms at least one meniscus between the deposition plate and the substrate;
driving the deposition plate to move relative to the platform or driving the platform to move relative to the deposition plate, enabling the second suspension to spread on the surface of the substrate in the second predetermined pattern; and
removing the suspension solvent on the substrate.

4. The method of claim 1, wherein the first predetermined pattern is in the form of one or more letters, one or more numbers, one or more words, one or more shapes, one or more trademarks, one or more logos, one or more pictures, or any combination thereof; the second predetermined pattern is in the form of one or more letters, one or more numbers, one or more words, one or more shapes, one or more trademarks, one or more logos, one or more pictures, or any combination thereof.

5. The method of claim 1, wherein the first particles are hydrophobic, and the second particles are hydrophilic; or the first particles are hydrophilic, and the second particles are hydrophobic.

6. The apparatus of claim 1, wherein the first particles are oleophobic, and the second nanoparticles are oleophilic; or the first particles are oleophilic, and the second particles are oleophobic.

7. The method of claim 2, wherein the first suspension comprises about 1%-50% the first nanoparticles by volume.

8. The method of claim 3, wherein the second suspension comprises about 1%-50% the second nanoparticles by volume.

9. The method of claim 2, wherein the acute angle is greater than 25 degrees.

10. The method of claim 3, wherein the acute angle is greater than 25 degrees.

11. The method of claim 9, wherein the acute angle is 60 degrees.

12. The method of claim 10, wherein the acute angle is 60 degrees.

13. The method of claim 2, wherein the end of the deposition plate is suspended above the substrate surface or the end of the deposition plate physically contacts the substrate.

14. The method of claim 3, wherein the end of the deposition plate is suspended above the substrate surface or the end of the deposition plate physically contacts the substrate.

15. A substrate comprising:
a surface;
a first particles deposited on the surface in a first predetermined pattern; and
a second particles that are nanoparticles deposited on the surface in a second predetermined pattern;
wherein the second particles are different from the first particles and repulsively interacts with the first particles, and the second predetermined pattern is such that it can be detected for preventing counterfeiting.

16. The substrate of claim 15, wherein the first predetermined pattern is in the form of one or more letters, one or more numbers, one or more words, one or more shapes, one or more trademarks, one or more logos, one or more pictures, or any combination thereof; the second predetermined pattern is in the form of one or more letters, one or more numbers, one or more words, one or more shapes, one or more trademarks, one or more logos, one or more pictures, or any combination thereof.

17. The substrate of claim 15, wherein the first particles are hydrophobic, and the second particles are hydrophilic; or the first particles are hydrophilic, and the second particles are hydrophobic.

18. The substrate of claim 15, wherein the first particles are oleophobic, and the second particles are oleophilic; or the first particles are oleophilic, and the second particles are oleophobic.
